(19) United States
(12) Patent Application Publication
(10) Pub. No.: US 2024/0047542 A1
(43) Pub. Date: Feb. 8, 2024

(54) SEMICONDUCTOR DEVICE AND METHOD OF MANUFACTURING THE SAME

(71) Applicant: TAIWAN SEMICONDUCTOR MANUFACTURING COMPANY LTD., HSINCHU (TW)

(72) Inventors: JHIH-BIN CHEN, HSINCHU (TW); HUNG-SHU HUANG, TAICHUNG CITY (TW); JHU-MIN SONG, NANTOU COUNTY (TW); CHIEN-CHIH CHOU, NEW TAIPEI CITY (TW); YU-CHANG JONG, HSINCHU CITY (TW); FEI-YUN CHEN, HSINCHU (TW)

(21) Appl. No.: 17/817,023

(22) Filed: Aug. 3, 2022

(51) Int. Cl. H01L 29/423; H01L 29/08; H01L 29/40; H01L 29/66

(52) U.S. Cl. CPC H01L 29/42368; H01L 29/0847; H01L 29/401; H01L 29/66621; H01L 29/66636

(57) ABSTRACT

A semiconductor device and a method of manufacturing a semiconductor device are provided. The semiconductor device includes a source region, a drain region, a gate region and a gate oxide. The gate region is disposed between the source region and the drain region. The gate oxide is disposed on the gate region. A bottom interface is between the gate region and the gate oxide, and an entire of the bottom interface is substantially flat.

### BACKGROUND

Industry requirements for decreased size in integrated circuits (ICs) have resulted in smaller devices which consume less power yet provide more functionality at higher speeds. The miniaturization process has also resulted in stricter design and manufacturing specifications as well as reliability challenges. The integrated circuit (IC) may include one or more high-voltage (HV) devices. However, a bird's beak effect under the corner of the gate oxide of the high-voltage (HV) device is an issue.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, dimensions of the various features may be arbitrarily increased or reduced for clarity of discussion.

FIG. 1 illustrates a cross-sectional view of an example of a semiconductor device according to some embodiments of the present disclosure.

FIG. 1A illustrates an enlarged view of an area “A” of FIG. 1.

FIG. 2 illustrates a cross-sectional view of an example of a semiconductor device according to some embodiments of the present disclosure.

FIG. 3, FIG. 4, FIG. 5, FIG. 6, FIG. 7, FIG. 8, FIG. 9 and FIG. 10 illustrate various stages in the manufacture of a semiconductor device, in accordance with some embodiments of the present disclosure.

FIG. 11 illustrates a flow chart of a method of manufacturing a semiconductor device in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

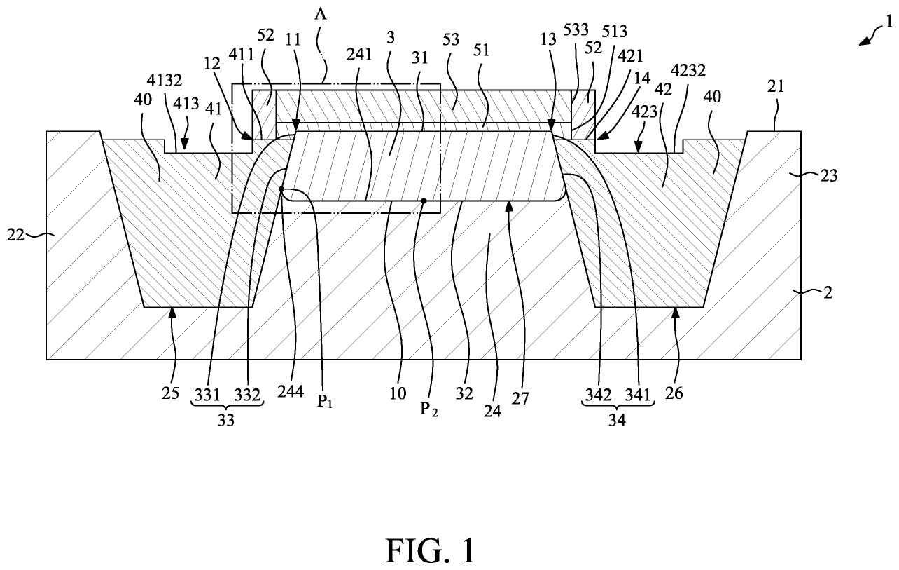

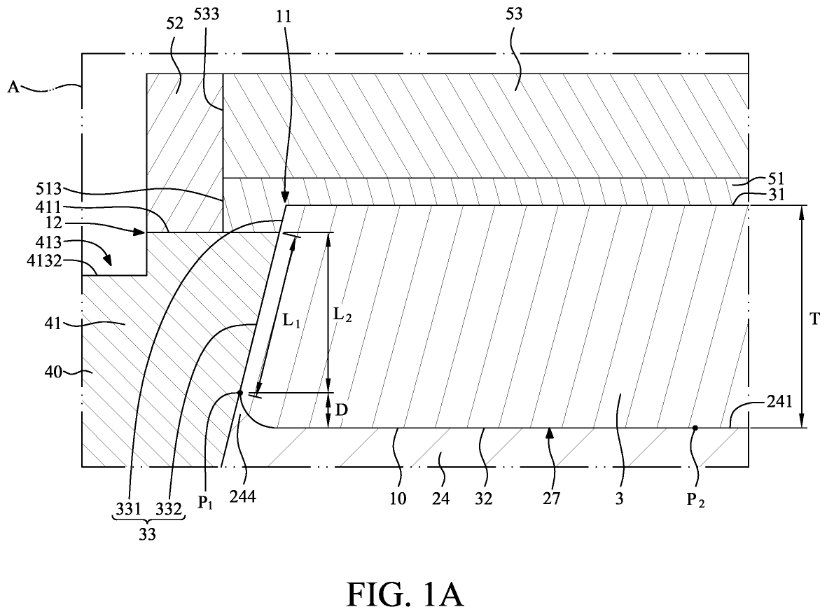

FIG. 1 illustrates a cross-sectional view of an example of a semiconductor device 1 according to some embodiments of the present disclosure. In some embodiments, the semiconductor device 1 may be a field effect transistor (FET) such as a metal-oxide-semiconductor field-effect transistor (MOSFET). In some embodiments, the semiconductor device 1 may be a high-voltage FET such as a high-voltage MOSFET.

The semiconductor device 1 may include a substrate 2, a gate oxide 3, an oxide layer 51, a metal gate 53 and a protection layer 52, a first trench isolation 41 and a second trench isolation 42. The substrate 2 may be a semiconductor substrate such as a silicon wafer. The substrate 2 has a top surface 21, and may include a source region 22, a drain region 23 and a gate region 24. The source region 22 may be doped with n-type dopant or p-type dopant. The drain region 23 may be doped with n-type dopant or p-type dopant. The substrate 2 may define a recess 27 recessed from the top surface 21 of the substrate 2. The recess 27 may be located on the gate region 24 for accommodating the gate oxide 3. Thus, a bottom surface of the recess 27 is a top surface 241 of the gate region 24. The top surface 241 of the gate region 24 is recessed from the top surface 21 of the substrate 2. Alternatively, the top surface 241 of the gate region 24 is lower than the top surface 21 of the substrate 2. In some embodiments, the top surface 241 of the gate region 24 contacting the gate oxide 3 may be a substantially flat surface.

The gate oxide 3 may be disposed in the recess 27, and may be disposed over or on the gate region 24. The gate oxide 3 may include silicon oxide, e.g., SiO₂, and may be formed through a thermal process. In some embodiments, the gate oxide 3 may be formed by conducting a thermal process to the gate region 24. That is, the gate oxide 3 may be formed from the oxidation of the gate region 24 after the thermal process. Thus, the gate oxide 3 may be a thermal oxide. The gate oxide 3 may have a top surface 31, a bottom surface 32, a first lateral surface 33 and a second lateral surface 34 opposite to the first lateral surface 33. The first lateral surface 33 and the second lateral surface 34 may extend between the top surface 31 and the bottom surface 32. The top surface 31 of the gate oxide 3 may be aligned with or leveled with the top surface 21 of the substrate 2 (e.g., a top surface of the source region 22 or a top surface of the drain region 23). That is, an elevation of the top surface 31 of the gate oxide 3 may be substantially the same as an elevation of the top surface 21 of the substrate 2.

The first lateral surface 33 may be adjacent to the first trench isolation 41, and may include an upper portion 331 and a lower portion 332. The upper portion 331 and the lower portion 332 are substantially coplanar with each other since they are formed concurrently. The upper portion 331 may protrude from or may be exposed from the first trench isolation 41, and covered by the oxide layer 51. The lower portion 332 may be in contact with the first trench isolation 41. Thus, the lower portion 332 of the first lateral surface 33 may be also referred to as “a first interface” between the gate oxide 3 and the first trench isolation 41. In some embodiments, a material of the gate oxide 3 may be the same as a material of the electrical insulation material 40 of the first trench isolation 41, thus, the first interface may be non-obvious or invisible.

Similarly, the second lateral surface 34 may be adjacent to the second trench isolation 42, and may include an upper portion 341 and a lower portion 342. The upper portion 341 and the lower portion 342 are substantially coplanar with each other since they are formed concurrently. The upper portion 341 may protrude from or may be exposed from the second trench isolation 42, and covered by the oxide layer 51. The lower portion 342 may be in contact with the second trench isolation 42. Thus, the lower portion 342 of the second lateral surface 34 may be also referred to as “a second interface” between the gate oxide 3 and the second trench isolation 42. In some embodiments, a material of the gate oxide 3 may be the same as a material of the electrical insulation material 40 of the second trench isolation 42, thus, the second interface may be non-obvious or invisible.

A bottom interface 10 may be formed between the gate region 24 and the gate oxide 3, and the entire bottom interface 10 may be substantially flat. In some embodiments, the bottom interface may be the bottom surface 32 of the gate oxide 3, or may be the top surface 241 of the gate region 24. The bottom interface 10 may be lower than the top surface 21 of the substrate 2. That is, an elevation of the bottom interface 10 may be lower than an elevation of the top surface 21 of the substrate 2. The gate oxide 3 may be embedded in the substrate 2.

The substrate 2 and the gate oxide 3 may jointly define a first trench 25 and a second trench 26 opposite to the first trench 25. The depth of the first trench 25 and the depth of the second trench 26 may be greater than the depth of the recess 27. An electrical insulation material 40 may be formed or disposed in the first trench 25 to form the first trench isolation 41. The first trench isolation 41 may have a top surface 411. The electrical insulation material 40 may include silicon oxide, e.g., SiO₂, and may be formed through a deposition process. The electrical insulation material 40 may be also formed or disposed in the second trench 26 to form the second trench isolation 42. The second trench isolation 42 may have a top surface 421. Each of the first trench isolation 41 and the second trench isolation 42 may be a shallow trench isolation (STI).

As shown in FIG. 1, the first trench isolation 41 may be disposed between the source region 22 and the gate region 24. The top surface 411 of the first trench isolation 41 may be lower than the top surface 31 of the gate oxide 3. Thus, the gate oxide 3 may protrude from the first trench isolation 41. Further, the top surface 411 of the first trench isolation 41 may be lower than the top surface 21 of the substrate 2 or the top surface 21 of the source region 22. That is, an elevation of the top surface 411 of the first trench isolation 41 may be lower than an elevation of the top surface 31 of the gate oxide 3, the top surface 21 of the substrate 2 and the top surface 21 of the source region 22. A first step structure 11 may be formed by the top surface 31 of the gate oxide 3, the upper portion 331 of the first lateral surface 33 of the gate oxide 3 and the top surface 411 of the first trench isolation 41. In some embodiments, in the first step structure 11, a difference between the elevation of the top surface 411 of the first trench isolation 41 and the elevation of the top surface 31 of the gate oxide 3 may be 0.5 nm to 5 nm. In addition, the first trench isolation 41 may define a recess 413 recessed from the top surface 411. Thus, a second step structure 12 may be formed by the top surface 411 of the first trench isolation 41 and the recess 413. In some embodiments, in the second step structure 12, a difference between the elevation of the top surface 411 of the first trench isolation 41 and an elevation of a bottom surface 4132 of the recess 413 may be 1 nm to 10 nm.

The second trench isolation 42 may be disposed between the drain region 23 and the gate region 24. Thus, the second trench isolation 42 may be opposite to the first trench isolation 41, and the gate region 24 may be disposed between the first trench isolation 41 and the second trench isolation 42. The top surface 421 of the second trench isolation 42 may be lower than the top surface 31 of the gate oxide 3. Thus, the gate oxide 3 may protrude from the second trench isolation 42. Further, the top surface 421 of the second trench isolation 42 may be lower than the top surface 21 of the substrate 2 or the top surface 21 of the drain region 23. That is, an elevation of the top surface 421 of the second trench isolation 42 may be lower than an elevation of the top surface 31 of the gate oxide 3, the top surface 21 of the substrate 2 and the top surface 21 of the drain region 23. A third step structure 13 may be formed by the top surface 31 of the gate oxide 3, the upper portion 341 of the second lateral surface 34 of the gate oxide 3 and the top surface 421 of the second trench isolation 42. In some embodiments, in the third step structure 13, a difference between the elevation of the top surface 421 of the second trench isolation 42 and the elevation of the top surface 31 of the gate oxide 3 may be 0.5 nm to 5 nm. In addition, the second trench isolation 42 may define a recess 423 recessed from the top surface 421. Thus, a fourth step structure 14 may be formed by the top surface 421 of the second trench isolation 42 and the recess 423. In some embodiments, in the fourth step structure 14, a difference between the elevation of the top surface 421 of the second trench isolation 42 and an elevation of a bottom surface 4232 of the recess 423 may be 1 nm to 10 nm.

The oxide layer 51 may include an electrical insulation material such as an oxide material. The oxide layer 51 may cover and contact the top surface 31 of the gate oxide 3, the upper portion 331 of the first lateral surface 33 of the gate oxide 3, the upper portion 341 of the second lateral surface 34 of the gate oxide 3, a portion of the top surface 411 of the first trench isolation 41 and a portion of the top surface 421 of the second trench isolation 42. Thus, the oxide layer 51 may cover and contact the first step structure 11 and the third step structure 13. A width of the oxide layer 51 may be greater than a width of the gate oxide 3. A thickness of a center portion of the oxide layer 51 may be less than a thickness of a periphery portion of the oxide layer 51. However, in some embodiments, the oxide layer 51 may have a consistent thickness, and may be conformal with the first step structure 11 and the third step structure 13. The oxide layer 51 may have a lateral surface 513.

The metal gate 53 may include a metal material. The metal gate 53 may be formed or disposed on the oxide layer 51. Thus, the metal gate 53 may be located right above the gate oxide 3. A thickness of the metal gate 53 may be greater than a thickness of the oxide layer 51. The metal gate 53 may have a lateral surface 533. A width of the metal gate 53 may be substantially equal to a width of the oxide layer 51. Thus, the lateral surface 533 of the metal gate 53 may be aligned with the lateral surface 513 of the oxide layer 51.

The protection layer 52 may be a nitride spacer. The protection layer 52 may be formed or disposed on the top surface 411 of the first trench isolation 41 and the top surface 421 of the second trench isolation 42, so as to cover the lateral surface 533 of the metal gate 53 and the lateral surface 513 of the oxide layer 51. A lateral surface of the protection layer 52 may be aligned with a sidewall of the recess 413 of the first trench isolation 41 and a sidewall of the recess 423 of the second trench isolation 42 since they are formed concurrently. That is, the second step structure 12 and the fourth step structure 14 are formed during the formation of the protection layer 52.

FIG. 1A illustrates an enlarged view of an area “A” of FIG. 1. The entire bottom interface 10 may be a substantially flat surface. In some embodiments, a difference or vertical distance D between an elevation of a highest point P₁ of the bottom interface 10 and an elevation of a lowest point P₂ of the bottom interface 10 (e.g., a center point P₂ of the bottom interface 10) is less than 1 nm or less than 0.5 nm. The highest point P₁ may be located at the end portion of the bottom interface 10. Alternatively, the highest point P₁ may be an intersection point between the bottom interface 10 and the lateral surface of the first trench isolation 41. Alternatively, the highest point P₁ may be an intersection point between the bottom interface 10 and the lower portion 332 of the first lateral surface 33 of the gate oxide 3. Alternatively, the highest point P₁ may be an intersection point between the lower portion 332 of the first lateral surface 33 of the gate oxide 3 and the top surface 241 of the gate region 24. Alternatively, the highest point P₁ may be an intersection point between the lower portion 332 of the first lateral surface 33 of the gate oxide 3 and the bottom surface 32 of the gate oxide 3. In some embodiments, the vertical distance D may be less than 50%, 40%, 30%, 20%, 10%, 5%, 3% or 1% of a thickness T of the gate oxide 3. As shown in FIG. 1A, the gate region 24 may have a little periphery protrusion 244 located at the periphery of the top surface 241 of the gate region 24. The height of the periphery protrusion 244 may be equal to the vertical distance D.

A first interface 332 (i.e., the lower portion 332 of the first lateral surface 33 of the gate oxide 3) is between the gate oxide 3 and the first trench isolation 41. A length L₁ of the first interface 332 (i.e., the lower portion 332 of the first lateral surface 33) may be greater than one half of the thickness T of the gate oxide 3. For example, the length L₁ of the first interface 332 may be greater than 60%, 70%, 80% or 90% of the thickness T of the gate oxide 3. Further, a length L₂ of a horizontal projection of the first interface 332 may be than one half of the thickness T of the gate oxide 3. For example, the length L₂ of the horizontal projection of the first interface 332 may be greater than 60%, 70%, 80% or 90% of the thickness T of the gate oxide 3. In addition, the length L₂ of the horizontal projection of the first interface 332 may be greater than the difference or vertical distance D between the elevation of the highest point P₁ of the bottom interface 10 and the elevation of a lowest point P₂ of the bottom interface 10. For example, the length L₂ may be greater than two times, three times, four times, five times, six times, ten times, twenty times, or one hundred times of the vertical distance D.

In the embodiment illustrated in FIG. 1 and FIG. 1A, the vertical distance D is very small. For example, the vertical distance D may approach to zero or may be equal to zero. Thus, an undesirable bird's beak effect may be reduced, eliminated or prevented. As a result, the electrical performance of the semiconductor device 1 may be improved, especially when the semiconductor device 1 is a high-voltage device.

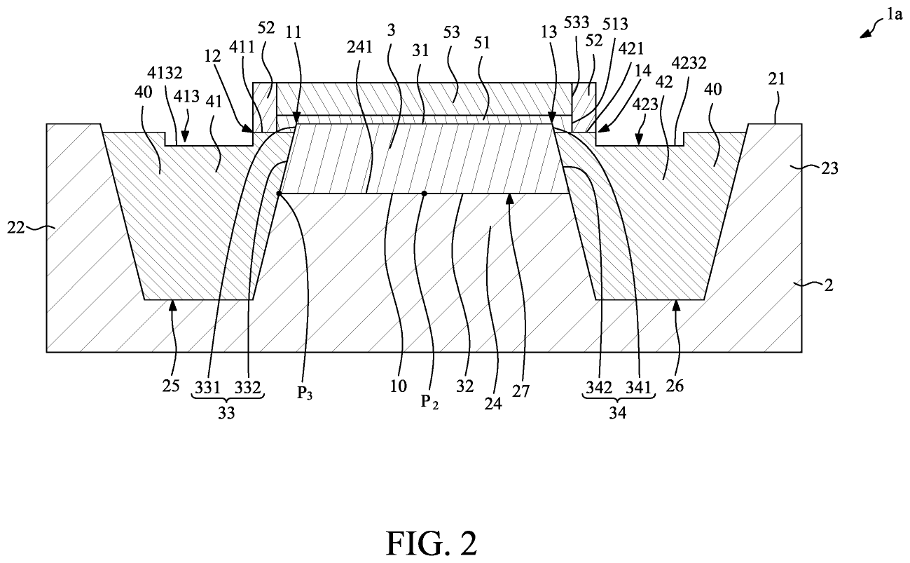

FIG. 2 illustrates a cross-sectional view of an example of a semiconductor device 1a according to some embodiments of the present disclosure. The semiconductor device 1a of FIG. 2 is similar to the semiconductor device 1 of FIG. 1, except that the entire bottom interface 10 or the entire top surface 241 of the gate region 24 is a flat surface. An intersection point P₃ may be defined as an intersection point between the bottom interface 10 and the lateral surface of the first trench isolation 41. Alternatively, the intersection point P₃ may be an intersection point between the bottom interface and the lower portion 332 of the first lateral surface 33 of the gate oxide 3. Alternatively, the intersection point P₃ may be an intersection point between the lower portion 332 of the first lateral surface 33 of the gate oxide 3 and the top surface 241 of the gate region 24. Alternatively, the intersection point P₃ may be an intersection point between the lower portion 332 of the first lateral surface 33 of the gate oxide 3 and the bottom surface 32 of the gate oxide 3.

As shown in FIG. 2, the intersection point P₃ and the center point P₂ of the top surface 241 of the gate region 24 are at a substantially same level. A difference or vertical distance between an elevation of the intersection point P₃ and an elevation of the center point P₂ of the bottom interface (e.g., the center point P₂ of the top surface 241 of the gate region 24) may be substantially equal to zero. As shown in FIG. 2, the gate region 24 does not have the periphery protrusion 244 of FIG. 1A. The top surface 241 of the gate region 24 extends horizontally to contact the lateral surface of the first trench isolation 41 at the intersection point P₃ without any elevation difference. The entire top surface 241 of the gate region 24 (or the entire bottom surface 32 of the gate oxide 3) is substantially parallel with the top surface 31 of the gate oxide 3.

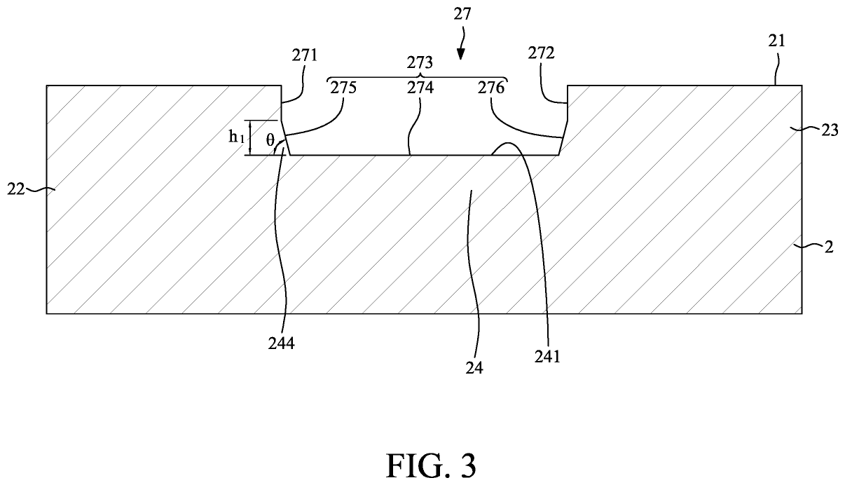

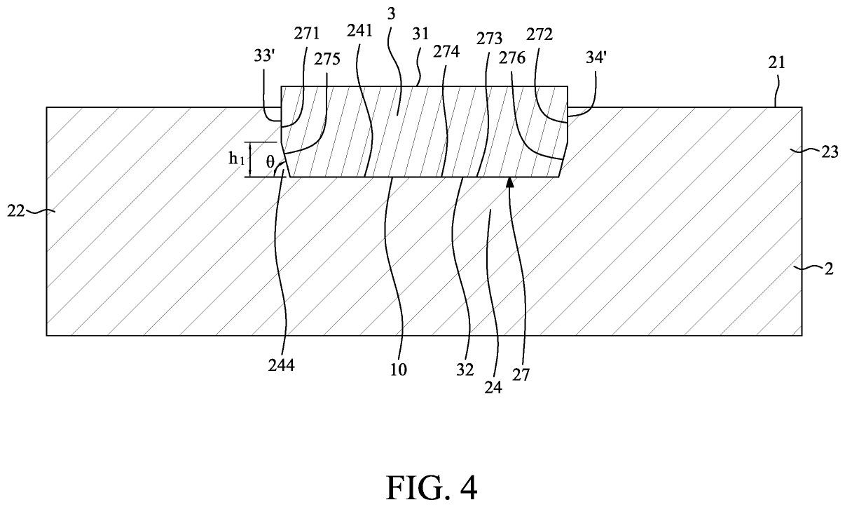

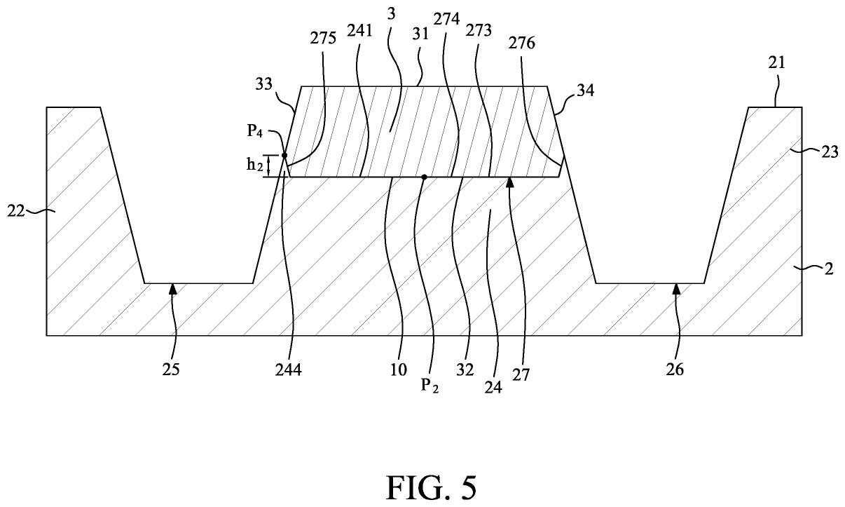

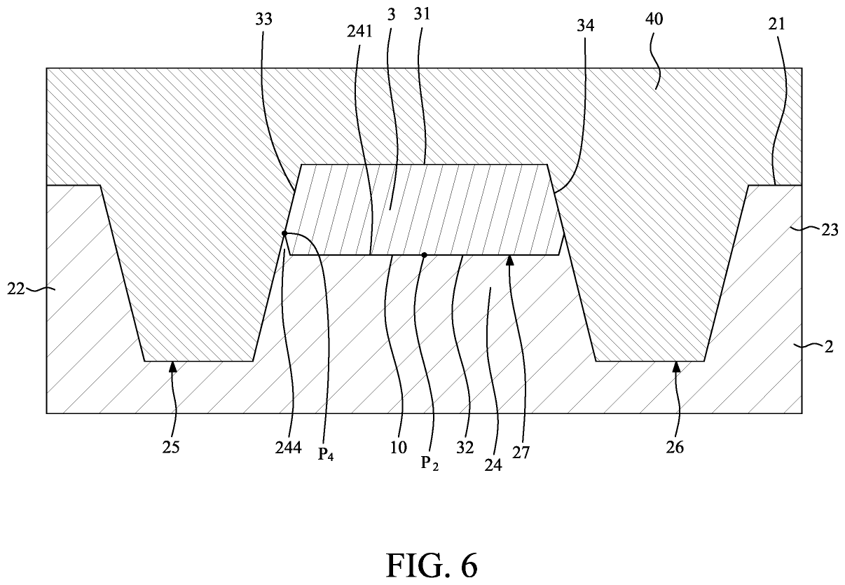

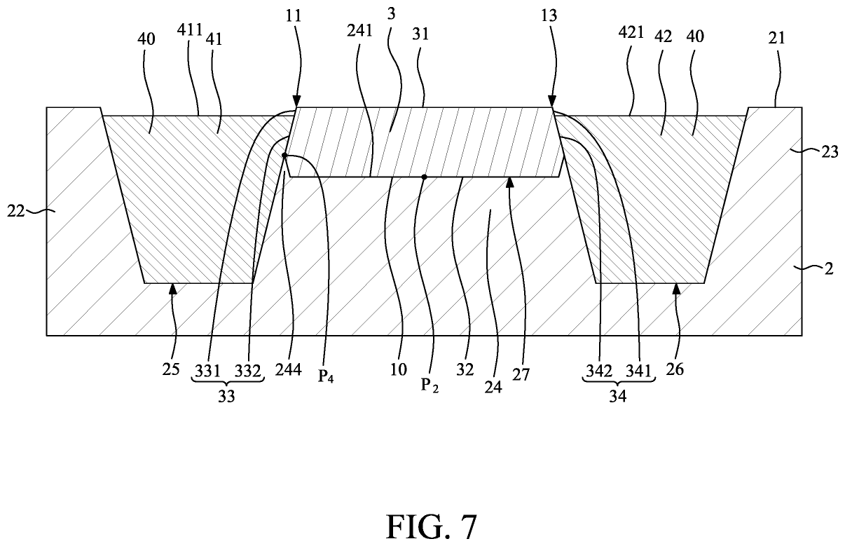

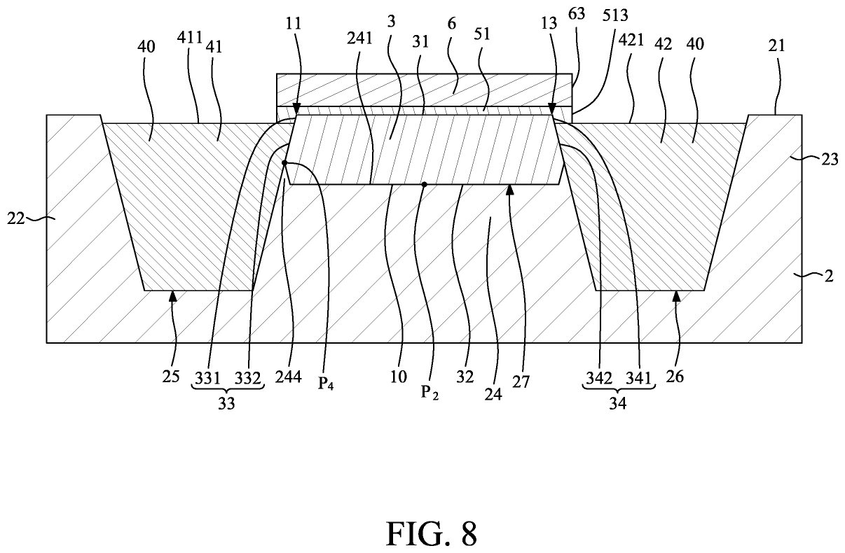

FIG. 3 through FIG. 10 illustrate a method for manufacturing a semiconductor device according to some embodiments of the present disclosure. In some embodiments, the method is for manufacturing the semiconductor device 1 shown in FIG. 1.

Referring to FIG. 3, a substrate 2 is provided. The substrate 2 can be, for example, silicon substrate. The substrate 2 has a top surface 21, and may include a source region 22, a drain region 23 and an intermediate region. The intermediate region is located between the source region 22 and the drain region 23. That is, the source region 22 and the drain region 23 are located at two opposite sides of the intermediate region. Then, a portion of the intermediate region may be removed to form a recess 27 and a gate region 24 under the recess 27. The recess 27 may be recessed from the top surface 21 of the substrate 2. The recess 27 and the gate region 24 are located between the source region 22 and the drain region 23. The recess 27 may have a first lateral sidewall 271, a second lateral sidewall 272 and a bottom surface 273. The first lateral sidewall 271 and the second lateral sidewall 272 may be substantially perpendicular to the top surface 21 of the substrate 2. The bottom surface 273 may include a main portion 274, a first slanted portion 275 and a second slanted portion 276 located at the periphery of the main portion 274. The first slanted portion 275 may connect the first lateral sidewall 271 and the main portion 274, and the second slanted portion 276 may connect the second lateral sidewall 276 and the main portion 274. For example, an inclination angle θ between the first slanted portion 275 and an extension of the main portion 274 may be 65 degrees to 85 degrees, or 70 degrees to 80 degrees. As shown in FIG. 3, the inclination angle θ may be 75 degrees. In some embodiments, the bottom surface 273 of the recess 27 may define a top surface 241 of the gate region 24. In addition, the gate region 24 may have a periphery protrusion 244 located at the periphery of the top surface 241 of the gate region 24. The periphery protrusion 244 may correspond to the first slanted portion 275 and the second slanted portion 276 of the bottom surface 273. The periphery protrusion 244 may have a height h₁. As shown in FIG. 3, the bottom corner portion of the recess 27 may be tapered or rounded due to the first slanted portion 275 and the second slanted portion 276 of the bottom surface 273. Thus, a stress concentration at the bottom corner portion of the recess 27 may be reduced.

Referring to FIG. 4, a gate oxide 3 may be formed or disposed in the recess 27, and may be disposed over or on the gate region 24. The gate oxide 3 may include silicon oxide, e.g., SiO₂, and may be formed through a thermal process or other suitable techniques. In some embodiments, the gate oxide 3 may be formed by conducting a thermal process to the gate region 24. That is, the gate oxide 3 may be formed from the oxidation of the gate region 24 after the thermal process. Thus, the gate oxide 3 may be a thermal oxide. The gate oxide 3 may have a top surface 31, a bottom surface 32, a first outer surface 33′ and a second outer surface 34′ opposite to the first outer surface 33′.

The first outer surface 33′ and the second outer surface 34′ may extend between the top surface 31 and the bottom surface 32. The first outer surface 33′ and the second outer surface 34′ of the gate oxide 3 may correspond to the first lateral sidewall 271 and the second lateral sidewall 272, respectively. The top surface 31 of the gate oxide 3 may be higher than the top surface 21 of the substrate 2 (e.g., a top surface of the source region 22 or a top surface of the drain region 23). That is, an upper portion of the gate oxide 3 may protrude from the top surface 21 of the substrate 2. The bottom surface 32 of the gate oxide 3 may correspond to the top surface 241 of the gate region 24 (e.g., the bottom surface 273 of the recess 27). A bottom interface 10 may be formed between the gate region 24 and the gate oxide 3. In some embodiments, the bottom interface 10 may be the bottom surface 32 of the gate oxide 3, or may be the top surface 241 of the gate region 24.

Referring to FIG. 5, a portion of the gate oxide 3 and a portion of the substrate 2 may be removed by, for example, etching, so as to form at least one trench in the substrate 2. In some embodiments, a portion of the gate oxide 3 adjacent to the first outer surface 33′ and a portion of the substrate 2 adjacent to the first outer surface 33′ may be removed so as to form a first trench 25. Meanwhile, a portion of the gate oxide 3 adjacent to the second outer surface 34′ and a portion of the substrate 2 adjacent to the second outer surface 34′ may be removed so as to form a second trench 26. Thus, the gate oxide 3 has a first lateral surface 33 and a second lateral surface 34 extending the between the top surface 31 and the bottom surface 32. The first lateral surface 33 may be exposed in the first trench 25, and the second lateral surface 34 may be exposed in the second trench 26. The first lateral surface 33 of the gate oxide 3 may be substantially coplanar with a sidewall of the first trench since they may be formed concurrently. That is, the first trench 25 may be defined by the substrate 2 and the first lateral surface 33 of the gate oxide 3. Further, the second lateral surface 34 of the gate oxide 3 may be substantially coplanar with a sidewall of the second trench 26 since they may be formed concurrently. That is, the second trench 26 may be defined by the substrate 2 and the second lateral surface 34 of the gate oxide 3.

In some embodiments, a portion of the periphery protrusion 244 of the gate region 24 may be also removed during the formation of the first trench 25 and the second trench 26. That is, a portion of the first slanted portion 275 and the second slanted portion 276 of the bottom surface 273 may be also removed during the formation of the first trench 25 and the second trench 26. Thus, the height of the periphery protrusion 244 may be reduced to h₂ from the height h₁ of FIG. 3. As shown in FIG. 5, the height h₂ may be equal to a difference or a vertical distance between an elevation of a highest point P₄ of the bottom interface 10 and an elevation of a lowest point P₂ of the bottom interface 10 (e.g., a center point P₂ of the bottom interface 10). The highest point P₄ may be located at the end portion of the bottom interface 10. Alternatively, the highest point P₄ may be an intersection point between the bottom interface 10 and the sidewall of the first trench 25. Alternatively, the highest point P₄ may be an intersection point between the bottom interface 10 and the first lateral surface 33 of the gate oxide 3. Alternatively, the highest point P₄ may be an intersection point between the first lateral surface 33 of the gate oxide 3 and the top surface 241 of the gate region 24. Alternatively, the highest point P₄ may be an intersection point between the first lateral surface 33 of the gate oxide 3 and the bottom surface 32 of the gate oxide 3.

Referring to FIG. 6, an electrical insulation material 40 may be formed or disposed on the top surface 21 of the substrate 2 and the top surface 31 of the gate oxide 3, and may extend into the first trench 25 and the second trench 26. The electrical insulation material 40 may include silicon oxide, e.g., SiO₂, and may be formed through a deposition process.

Referring to FIG. 7, a portion of the electrical insulation material 40 on the top surface 21 of the substrate 2 and the top surface 31 of the gate oxide 3 may be removed by, for example, chemical mechanical polishing (CMP) process and cleaning process. Meanwhile, the top surface 31 of the gate oxide 3 may be aligned with or leveled with the top surface 21 of the substrate 2 (e.g., a top surface of the source region 22 or a top surface of the drain region 23). That is, an elevation of the top surface 31 of the gate oxide 3 may be substantially the same as an elevation of the top surface 21 of the substrate 2. In addition, the electrical insulation material 40 in the first trench 25 may form a first trench isolation 41, and the electrical insulation material 40 in the second trench 26 may form a second trench isolation 42.

The top surface 411 of the first trench isolation 41 may be lower than the top surface 31 of the gate oxide 3. That is, the top surface 31 of the gate oxide 3 may be higher than the top surface 411 of the electrical insulation material 40 in the first trench 25. Thus, the gate oxide 3 may protrude from the first trench isolation 41. Further, the top surface 411 of the first trench isolation 41 may be lower than the top surface 21 of the substrate 2 or the top surface 21 of the source region 22. The first lateral surface 33 of the gate oxide 3 may include an upper portion 331 and a lower portion 332. The upper portion 331 may protrude from or may be exposed from the first trench isolation 41. A first step structure 11 may be formed by the top surface 31 of the gate oxide 3, the upper portion 331 of the first lateral surface 33 of the gate oxide 3 and the top surface 411 of the first trench isolation 41.

The top surface 421 of the second trench isolation 42 may be lower than the top surface 31 of the gate oxide 3. That is, the top surface 31 of the gate oxide 3 may be higher than the top surface 421 of the electrical insulation material 40 in the second trench 26. Thus, the gate oxide 3 may protrude from the second trench isolation 42. Further, the top surface 421 of the second trench isolation 42 may be lower than the top surface 21 of the substrate 2 or the top surface 21 of the drain region 23. The second lateral surface 34 of the gate oxide 3 may include an upper portion 341 and a lower portion 342. The upper portion 341 may protrude from or may be exposed from the second trench isolation 42. A third step structure 13 may be formed by the top surface 31 of the gate oxide 3, the upper portion 341 of the second lateral surface 34 of the gate oxide 3 and the top surface 421 of the second trench isolation 42.

Referring to FIG. 8, an oxide layer 51 may formed or disposed to cover and contact the top surface 31 of the gate oxide 3, the upper portion 331 of the first lateral surface 33 of the gate oxide 3, the upper portion 341 of the second lateral surface 34 of the gate oxide 3, a portion of the top surface 411 of the first trench isolation 41 and a portion of the top surface 421 of the second trench isolation 42. Thus, the oxide layer 51 may cover and contact the first step structure 11 and the third step structure 13. Then, a dummy layer 6 may be formed or disposed on the oxide layer 51. The lateral surface 63 of the dummy layer 6 may be aligned with the lateral surface 513 of the oxide layer 51.

Referring to FIG. 9, a protection layer 52 may be formed or disposed on the top surface 21 of the substrate 2, the top surface 411 of the first trench isolation 41 and the top surface 421 of the second trench isolation 42, so as to cover the lateral surface 63 of the dummy layer 6 and the lateral surface 513 of the oxide layer 51.

Referring to FIG. 10, a portion of the protection layer 52 may be removed by, for example, etching. In some embodiments, a recess 413 may be formed on the first trench isolation 41 and may be recessed from the top surface 411. Thus, a second step structure 12 may be formed by the top surface 411 of the first trench isolation 41 and the recess 413. Meanwhile, a recess 423 may be formed on the second trench isolation 42 and may be recessed from the top surface 421. Thus, a fourth step structure 14 may be formed by the top surface 421 of the second trench isolation 42 and the recess 423. A lateral surface of the protection layer 52 may be aligned with a sidewall of the recess 413 of the first trench isolation 41 and a sidewall of the recess 423 of the second trench isolation 42 since they are formed concurrently. That is, the second step structure 12 and the fourth step structure 14 are formed during the etching process of the protection layer 52.

Then, the source region 22 and the drain region 23 may be doped with n-type dopant or p-type dopant. Then, the dummy layer 6 may be removed to form an empty space. Then, a metal gate 53 (FIG. 1) may be formed or disposed in the empty space. That is, the metal gate 53 may replace the dummy layer 6, and may be disposed on the oxide layer 51. Thus, the metal gate 53 may be located right above the gate oxide 3. The metal gate 53 may have a lateral surface 533. A width of the metal gate 53 may be substantially equal to a width of the oxide layer 51. Thus, the lateral surface 533 of the metal gate 53 may be aligned with the lateral surface 513 of the oxide layer 51 and covered by the protection layer 52.

Then, after an annealing process of a back end of line (BEOL), the size of the periphery protrusion 244 of the gate region 24 may be further reduced as shown in FIG. 1. That is, the height h 2 of the periphery protrusion 244 of the gate region 24 as shown in FIG. 5 may be reduced to the vertical distance D of FIG. 1. The highest point of the bottom interface 10 may be lowered from the point P₄ (FIG. 10) to the point P₃ (FIG. 1). Thus, the semiconductor device 1 of FIG. 1 is obtained. As shown in FIG. 1, a length L₁ of a first interface 332 (i.e., the lower portion 332 of the first lateral surface 33) between the gate oxide 3 and the electrical insulation material 40 may be greater than one half of the thickness T of the gate oxide 3.

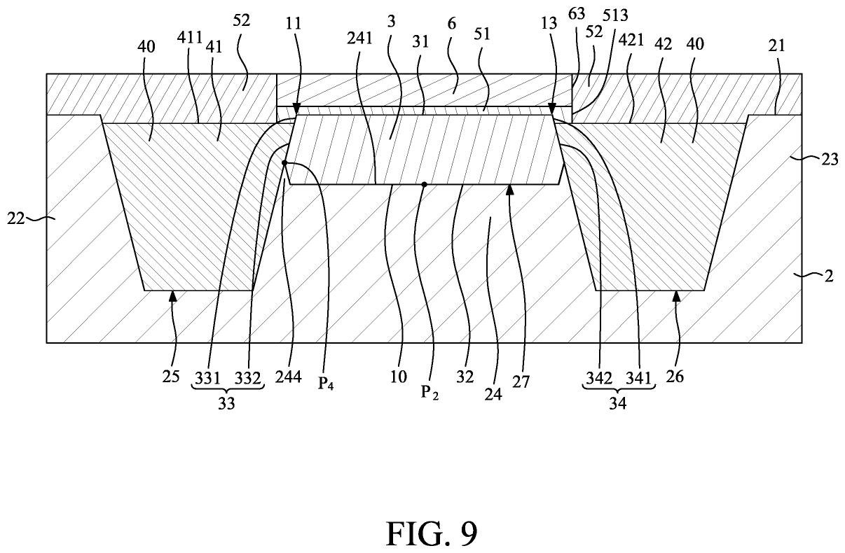

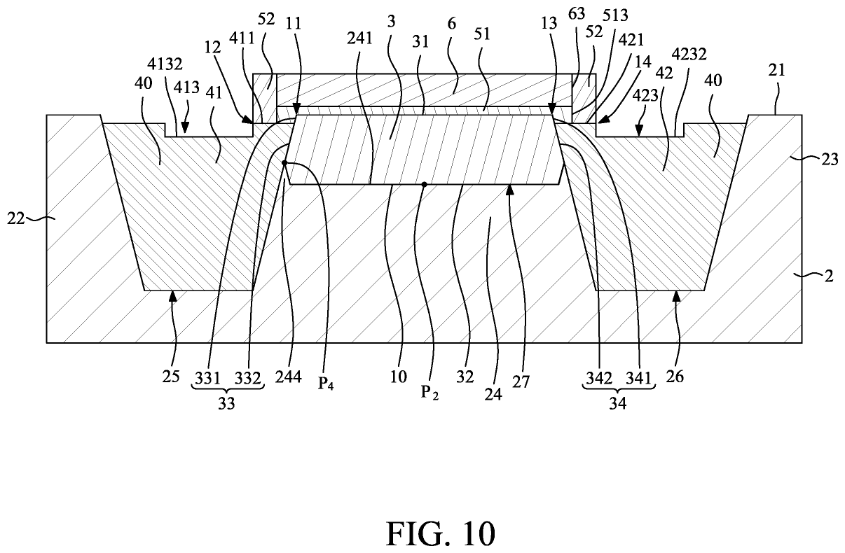

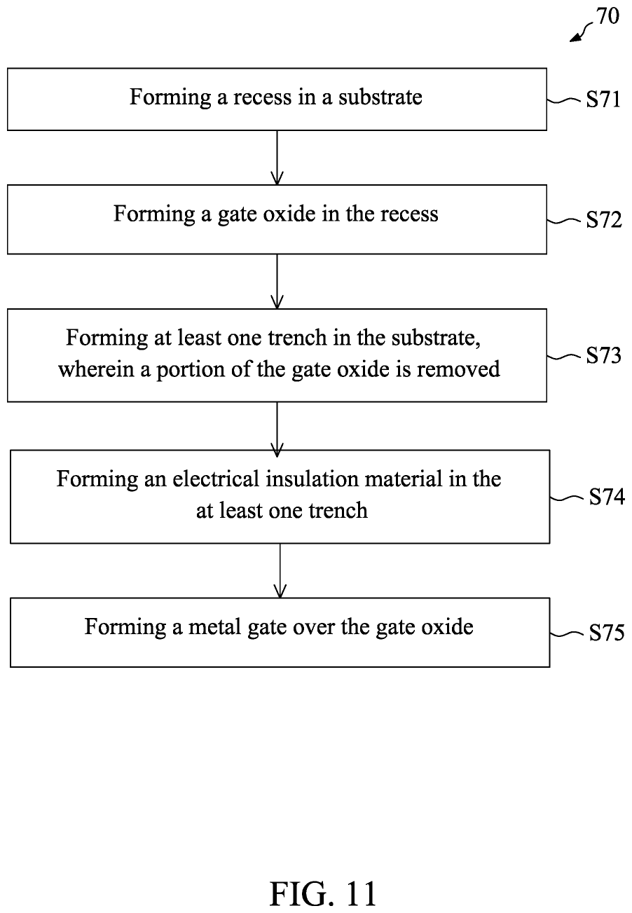

FIG. 11 illustrates a flow chart of a method 70 of manufacturing a semiconductor device 1 in accordance with some embodiments of the present disclosure.

In some embodiments, the method 70 may include a step S71, forming a recess in a substrate. For example, as shown in FIG. 3, the recess 27 may be formed in the substrate 2.

In some embodiments, the method 70 may include a step S72, forming a gate oxide in the recess. For example, as shown in FIG. 4, the gate oxide 3 may be formed in the recess 27.

In some embodiments, the method 70 may include a step S73, forming at least one trench in the substrate, wherein a portion of the gate oxide is removed. For example, as shown in FIG. 5, the first trench 25 and the second trench 26 may be formed in the substrate 2. A portion of the gate oxide 3 may be removed.

In some embodiments, the method 70 may include a step S74, forming an electrical insulation material in the at least one trench. For example, as shown in FIG. 6 and FIG. 7, the electrical insulation material 40 may be formed in the first trench 25 and the second trench 26.

In some embodiments, the method 70 may include a step S75, forming a metal gate over the gate oxide. For example, as shown in FIG. 1, the metal gate 53 may be formed over the gate oxide 3.

In accordance with some embodiments of the present disclosure, a semiconductor device includes a source region, a drain region, a gate region and a gate oxide. The gate region is disposed between the source region and the drain region. The gate oxide is disposed on the gate region. A bottom interface is between the gate region and the gate oxide, and an entire of the bottom interface is substantially flat.

In accordance with some embodiments of the present disclosure, a semiconductor device includes a first trench isolation, a second trench isolation, a gate region and a gate oxide. The second trench isolation is opposite to the first trench isolation. The gate region is disposed between the first trench isolation and the second trench isolation. The gate oxide is disposed over the gate region. The gate oxide protrudes from the first trench isolation and the second trench isolation.

In accordance with some embodiments of the present disclosure, a method of manufacturing a semiconductor device includes: forming a recess in a substrate; forming a gate oxide in the recess; forming at least one trench in the substrate, wherein a portion of the gate oxide is removed; forming an electrical insulation material in the at least one trench; and forming a metal gate over the gate oxide.

The foregoing outlines features of several embodiments so that those skilled in the art may better understand aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a source region;
a drain region;
a gate region disposed between the source region and the drain region; and
a gate oxide disposed on the gate region, wherein a bottom interface is between the gate region and the gate oxide, and an entire of the bottom interface is substantially flat.

2. The semiconductor device of claim 1, wherein a difference between an elevation of a highest point of the bottom interface and an elevation of a lowest point of the bottom interface is less than 1 nm.

3. The semiconductor device of claim 1, further comprising:
a first trench isolation disposed between the source region and the gate region, wherein a top surface of the first trench isolation is lower than a top surface of the gate oxide; and
a second trench isolation disposed between the drain region and the gate region, wherein a top surface of the second trench isolation is lower than the top surface of the gate oxide.

4. The semiconductor device of claim 3, wherein the top surface of the first trench isolation is lower than a top surface of the source region, and the top surface of the second trench isolation is lower than a top surface of the drain region.

5. The semiconductor device of claim 3, wherein a first interface is between the gate oxide and the first trench isolation, wherein in a cross-sectional view, a length of the first interface is greater than one half of a thickness of the gate oxide.

6. The semiconductor device of claim 5, wherein in the cross-sectional view, a length of a horizontal projection of the first interface is greater than one half of the thickness of the gate oxide.

7. The semiconductor device of claim 1, wherein a top surface of the gate oxide is substantially aligned a top surface of the source region or a top surface of the drain region.

8. The semiconductor device of claim 1, further comprising a metal gate disposed over the gate oxide.

9. A semiconductor device, comprising:
a first trench isolation;
a second trench isolation opposite to the first trench isolation;
a gate region disposed between the first trench isolation and the second trench isolation; and
a gate oxide disposed over the gate region, wherein the gate oxide protrudes from the first trench isolation and the second trench isolation.

10. The semiconductor device of claim 9, wherein the gate oxide has a first lateral surface adjacent to the first trench isolation and a second lateral surface adjacent to the second trench isolation, wherein a portion of the first lateral surface is exposed from the first trench isolation, and a portion of the second lateral surface is exposed from the second trench isolation.

11. The semiconductor device of claim 10, wherein an upper portion of the first lateral surface is exposed from the first trench isolation, a lower portion of the first lateral surface is in contact with the first trench isolation, an upper portion of the second lateral surface is exposed from the second trench isolation, and a lower portion of the second lateral surface is in contact with the second trench isolation.

12. The semiconductor device of claim 11, wherein in a cross-sectional view, a length of the lower portion of the first lateral surface is greater than one half of a thickness of the gate oxide.

13. The semiconductor device of claim 11, wherein the gate region has a top surface contacting the gate oxide, and the top surface of the gate region is a substantially flat surface.

14. The semiconductor device of claim 13, wherein in a cross-sectional view, the lower portion of the first lateral surface intersects with the top surface of the gate region at an intersection point, and the intersection point and a center point of the top surface of the gate region are at a substantially same level.

15. The semiconductor device of claim 14, wherein a difference between an elevation of the intersection point and an elevation of the center point is less than 1 nm.

16. A method of manufacturing a semiconductor device, comprising:
forming a recess in a substrate;
forming a gate oxide in the recess;
forming at least one trench in the substrate, wherein a portion of the gate oxide is removed;
forming an electrical insulation material in the at least one trench; and
forming a metal gate over the gate oxide.

17. The method of claim 16, wherein a top surface of the gate oxide is higher than a top surface of the substrate.

18. The method of claim 16, wherein the at least one trench is defined by the substrate and the gate oxide.

19. The method of claim 16, wherein a top surface of the gate oxide is higher than a top surface of the electrical insulation material in the at least one trench.

20. The method of claim 16, wherein a length of an interface between the gate oxide and the electrical insulation material is greater than one half of a thickness of the gate oxide.
